(19) United States
(12) Patent Application Publication
(10) Pub. No.: US 2006/0086317 A1
(43) Pub. Date: Apr. 27, 2006

(54) Automobile door holder or automobile lid holder

(76) Inventor: Heinz Fiedler, Goslar (DE)

Correspondence Address: PATRICK W. RASCHE;ARMSTRONG TEASDALE LLP, ONE METROPOLITAN SQUARE, SUITE 2600, ST. LOUIS, MO, 63102-2740, US

(21) Appl. No.: 10/519,755

(22) PCT Filed: Jun. 26, 2003
(86) PCT No.: PCT/EP03/06794

§ 371 Date: Oct. 31, 2005

(30) Foreign Application Priority Data
Jul. 1, 2002 (DE) 202 10 136.3

(51) Int. Cl. H01L 21/306; B05C 13/00

(52) U.S. Cl. 118/500; 156/345.51

(57) ABSTRACT

An automobile door or compartment-cover holder to fix in position a door or a cover for an engine or luggage compartment of an automobile during a processing event in the manufacturing procedure, in particular the application of a CDP coating and/or paint, constructed as a multi-part plastic holder or combined plastic-metal holder with contact or engagement sections disposed at or near several ends to cooperate with engagement sections on parts of the vehicle body in order to fix the components at a pre-specified distance from one another, such that the engagement sections have a substantially peg-like structure or are shaped like a flat hook, and each set of two contact or engagement sections is connected together by way of a holder section that extends linearly or is bent at substantially a right angle.

### CROSS REFERENCE TO RELATED APPLICATIONS

This application claims benefit of German Patent Application Number 202 10 136.3 filed Jul. 1, 2002

which is hereby incorporated by reference in its entirety.

### BACKGROUND OF THE INVENTION

This invention relates generally to a holder for supporting an automobile door or compartment cover during construction of the vehicle.

Processing means (holders for automobile doors or compartment covers) of the kind in question, also termed production accessories, have the function of keeping add-on parts, such as doors and the covers for luggage and engine compartments, at a specified distance from the basic body of the vehicle, in order to prevent these add-on parts from touching or impacting against the basic body, e.g. during a painting operation. These processing means or spacer devices are inserted after the body itself has been assembled, prior to its passage through the pretreatment stages, which consist of degreasing, rinsing, phosphatizing and cathodal electrophoresis plus dip priming (herinafter termed CDP). After the CDP coating has been heat-cured at temperatures up to 220° C. in a forced-air oven, the primed body is ready for the final paint application.

These processing means are constructed specifically for the particular area of application and model of vehicle concerned and at present, in practice, are made of steel and intended to be usable in various ways. Specially and elaborately configured fixation and/or engagement sections are provided to make contact with the basic body on one hand and the add-on parts on the other hand, so as to avoid damage to the vulnerable surfaces. In view of this situation, and because of the material employed, the known processing means are relatively expensive.

Because these holding devices are also coated during the painting process, every time they are used or pass through the processing sequence they must have this paint removed, whether mechanically, thermally or chemically, which involves high costs. This measure is necessary in order to avoid contamination of the newly coated or painted body surface by fragments of paint that might otherwise flake off the processing means during the required manipulations, such as opening the add-on parts so that installations in the interior of the vehicle can be carried out.

For paint removal, the following steps are required. After the processing means have been disassembled (removed) they must be sorted according to type. Because during the painting process the movable parts of the processing means, such as screws, brackets etc., lose their mobility and hence become nonfunctional, their mobility must be manually restored. After paint removal it is necessary firstly to test whether any paint residues are still present on the processing means, and secondly to determine whether the objects have been bent out of shape so that they are no longer usable. If the quality requirements have not been fulfilled, the processing means must again be passed through the paint-removal process, after type-sorting, or be repaired.

A multiple utilization of the fixation elements can be achieved only by labor- and cost-intensive subsequent treatment after use, and even then there is always a residual risk regarding their quality, which may cause a vehicle proceeding along the assembly line to require refinishing and thus impose additional costs.

The entire paint-removal operation must therefore be performed by either the subcontractor or the manufacturer of the vehicle, although it is not in principle the responsibility of either of these, and is uneconomical for them. Resources such as space, personnel (workers), management and the like must be provided, and hence are not available for other tasks. On the other hand, performance of these tasks at source (by the manufacturer of the processing means), at least in the workshops of origin, is ruled out by the excessive cost and effort of transport and the enormous stocks of these processing means that would have to be available. Furthermore, the effort involved in paint removal is costly in any case—regardless of who must bear the expense.

Another consideration, apart from the expense, is that paint removal is not sensible regarding the overall ecological balance, because removal of a coating necessarily involves large emissions of waste gases and produces residues potentially harmful to the environment.

Finally, manipulation of the conventional precision processing means made of steel requires some training and great care, which necessitates the employment of qualified and highly paid workers, or else the installation of robots designed to operate with high precision.

Therefore the document WO 03/004173 A1, which originated with the applicant, proposes a novel processing means that is constructed as a plastic holder with two contact or engagement sections disposed near its ends, and is to be inserted between two body parts during a processing procedure. Preferably this plastic holder is made to a substantial extent of recycled material, so that during the production process, in particular during manipulation of these holders, substantial simplifications and savings are achieved in comparison to holders that are made of steel and need to be elaborately cleaned after each use.

However, it has been found that for certain kinds of application further improvements of this novel plastic processing means are possible.

It is thus the objective of the present invention to disclose a processing means of this generic kind that is further improved functionally and is easy to manipulate.

This objective is achieved by a holder for an automobile door or compartment cover according to Claim 1 or 2. Advantageous further developments of the idea underlying the invention are the subject matter of the dependent claims.

After intensive practical experiments plastic materials suitable for such holders have been found that have the required properties and can be used for injection molding. The materials to be preferentially considered in this regard are thermally stable plastics that can be used in the long term at temperatures above 170° C., such as polysulfone, poly(acrylether)ketone, poly(ethersulfone), ABS (acrylonitrile/butadiene/styrol), but in particular polyamides.

Particularly suitable plastics are those reinforced with fibers of, e.g., glass, carbon, kevlar etc. An especially suitable material, with respect to cost of acquisition, recyclability, injection molding (optimal flow behavior) and mechanical properties even at high temperatures like those used for heat-curing, has proved to be polyamide reinforced with glass fibers. The elasticity of shape of the above-mentioned plastics and the bending behavior of the structurally adapted holding, bracket and engagement sections made of these materials enable easy insertion into the openings provided for the purpose in the add-on components and/or the basic body of the vehicle. Hence on one hand the danger of damaging adjacent surfaces is decidedly less than is the case for the known metal processiing means, which are hard and can bend only slightly or not at all, while on the other hand the processing means in accordance with the invention functions with high reliability and precision.

The above advantages can be demonstrated in particular when the plastic is reinforced by fillers in a proportion between 0.1 and 40%. Within this range of variation of filling, depending on the requirements for good flow behavior during injection molding and an appropriate shape stability and firmness of the processing means during the painting process, a desirable optimum can be attained.

The processing means in accordance with the invention are in particular first produced by the injection-molding procedure and then, when they have been used once or at least after they have been used for a limited number of times, are pulverized; where appropriate, this grinding can be done after the paint has been removed by methods known per se. The resulting powder can then be re-used directly to construct new processing means.

During injection molding in a recycling system it is advantageous for a certain amount—preferably about 5-30%, in particular 10%—of the original raw material to be added. This can be useful in particular if the quality of the paint-contaminated plastic recycling material is no longer satisfactory. By addition of the original raw material the functionality of the processing means can be maintained, with the advantages cited above.

The peg- or hook-shaped contact or engagement sections of the proposed plastic processing means are of course constructed so as to be adapted to the body configuration of the particular vehicle concerned and the specific design of the door-locking regions, lock reinforcements etc. of the add-on components; however, they are characterized by the fact that the elasticity of the plastic material selected and that of their shape are adjusted accordingly. The result is that the holders are easily handled, even by semiskilled workers, with no danger of damage to the adjacent surfaces. The above-mentioned shape elasticity is implemented, for example, by suitably dimensioned and oriented edging, hook, spring or spiral elements. The degree of shape elasticity is determined not only by the selection of the basic plastic material, but also by choosing a suitable filling material or fiber reinforcement and by the proportion thereof that is chosen.

The insertion of plastic holders between the body and add-on parts that are to be spaced apart from one another, and the removal of the add-ons after the manufacturing process (in particular, painting), are likewise facilitated by the flexural elasticity of the rods, extension arms, plates and the like that make up the basic structure of the plastic holder. The above-mentioned fiber-reinforced plastics make it easily possible to design the holders so that they have the desired flexibility.

The proposed materials just as easily enable the holders to be molded with suitably shaped handling sections, which allow installation by robots in that they are adapted to the gripping tools of the robots. In principle it is also true for robot assembly that the advantages for manipulation provided by the material allow the demands for precision in the movement sequences to be less severe, which enables more economical solutions to be derived.

In a first preferred embodiment the proposed holder has a handling section in the shape of a bent bar or a substantially flat plate and is designed to be either grasped manually or engaged by a gripping tool of a handling robot. As a result it can be employed both on assembly lines where the fixation of movable body parts for the CDP bath or the painting step is done by hand and also those where this is performed by a robot.

In a first, basic embodiment the proposed holder is a door hook, with two hooks to engage the window shaft of a door and at least one peg to engage an opening in the door provided for attaching a door lining. This door hook can additionally—as an alternative to the above-mentioned feature or in combination therewith—be distinguished by an extension section defined by the part of the holder that connects the engagement sections; in this case the substantially plate-shaped handling section has the shape of a circular ring in plan view and lies in a plane parallel to the extension plane of the door hook. In another advantageous design the door hook is constructed in two parts: one is a basic structure with several engagement sections to engage openings in a vehicle door as well as, if desired, openings or bearing surfaces in or on an adjacent part of the vehicle body, and the other is a substantially L-shaped pivotable bar that can be set onto the basic structure and has engagement sections to engage openings or to bear against parts of the vehicle body in the vicinity of the door. A door holder with these features can be reliably employed for various processing steps (CDP bath and/or painting).

In the case of the holder or rod designed to support a compartment cover and comprising a first and a second plastic part, the second plastic part has a substantially cuboid external shape, with a cylindrical first recess to engage the peg of the first plastic part and at least one elongated second recess to engage a section of a vehicle-body part, in particular a metal strap. This measure enables the holder to be easily inserted into the body opening and subsequently removed therefrom.

A design that is especially advantageous in connection with manipulation of the holder by a robot is distinguished by a locking device that can be locked in position or released by the linear displacement of two plastic parts with respect to one another; this is used for fixing the door or compartment cover of an automobile at a predetermined distance from the basic body of the vehicle, and to release it from this fixed position. Here it is provided in particular that the U-shaped or substantially plate-shaped handling section is mounted on the locking device and serves keep it in position and release it.

### BRIEF DESCRIPTION OF THE INVENTION

In one aspect, an automobile door or compartment-cover holder to fix in position a door or a cover for an engine or luggage compartment of an automobile during a processing event in the manufacturing procedure, in particular the application of a CDP coating and/or paint, constructed as a multi-part plastic holder or combined plastic-metal holder with contact or engagement sections disposed at or near more than one end to cooperate with engagement sections on parts of the vehicle body in order to fix the components at a pre-specified distance from one another, such that the engagement sections have a substantially peg-like structure or are shaped like a flat hook, and each set of two contact or engagement sections is connected together by way of a holder section that extends linearly or is bent at substantially a right angle.

In another aspect, an automobile door or compartment-cover holder to fix in position a door or a cover for an engine or luggage compartment of an automobile during a processing event in the manufacturing procedure, in particular the application of a CDP coating and/or paint, constructed as a multi-part plastic holder or combined plastic-metal holder with contact or engagement sections disposed at or near more than one end to cooperate with engagement sections on parts of the vehicle body in order to fix the components at a pre-specified distance from one another, comprising an elongated first plastic part, at the one end of which is provided an engagement section, in particular having a sleeve shape, to engage an elongation rod, and its other end bears a second plastic part, pivotally mounted on a peg that projects perpendicular to the longitudinal extent of the first plastic part, for the purpose of engaging an engagement section of an engine-compartment cover or a luggage-compartment cover.

### BRIEF DESCRIPTION OF THE DRAWINGS

Further advantages and useful features of the invention will be apparent from the subordinate claims and from the following description of preferred exemplary embodiments with reference to the figures, wherein:

FIGS. 1A to 1C show a basic structure of a door hook according to a first embodiment of the invention, in front, plan and side views,

FIGS. 2A and 2B show a pivoted L-bar that together with the basic structure according to FIGS. 8A to 8B forms a door hook, in front and plan views,

FIGS. 3A to 3C show a door hook in which the basic structure and the pivoted L-bar are combined, in front, plan and side views,

FIGS. 4A to 4E are various views of two parts of a cover hook to support the raised cover of an engine compartment, according to another embodiment of the invention,

FIG. 5 is a side view of the cover hook assembled from the individual parts according to FIGS. 11A to 11E,

FIGS. 6A to 6D show a door hook comprising a basic structure and a sliding element according to another embodiment of the invention, as seen from the front and side in the locked state (FIGS. 6A, 6B) and unlocked state (FIGS. 6C, 6D),

FIGS. 7A and 7B are a front view and a side view of the associated basic structure,

FIGS. 8A and 8B are a front view and a side view of the associated sliding bar,

FIGS. 9A to 9C show another door hook comprising basic structure and sliding element in front and side views, in the locked state (FIGS. 9A, 9B) and unlocked state (FIGS. 9C, 9D), and

FIG. 10 shows the sliding element associated therewith from the front and the side.

### DETAILED DESCRIPTION OF THE INVENTION

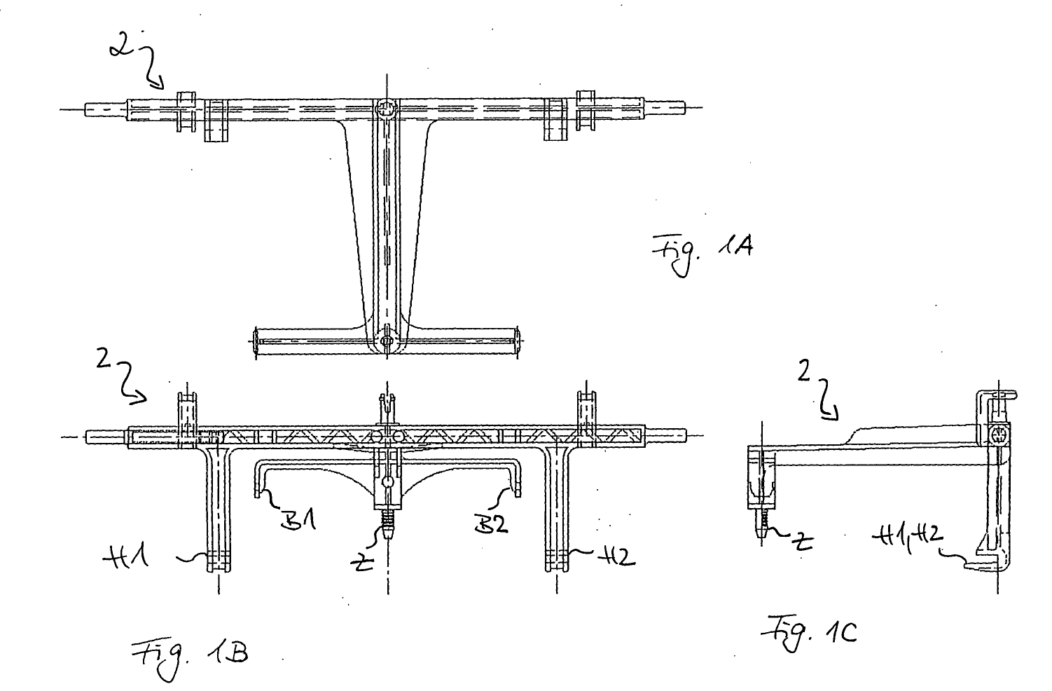

In FIGS. 1A to 3C is shown—in a manner essentially self-explanatory for a person skilled in the art—a first embodiment of a door hook 1 in accordance with the invention, viewed from various aspects.

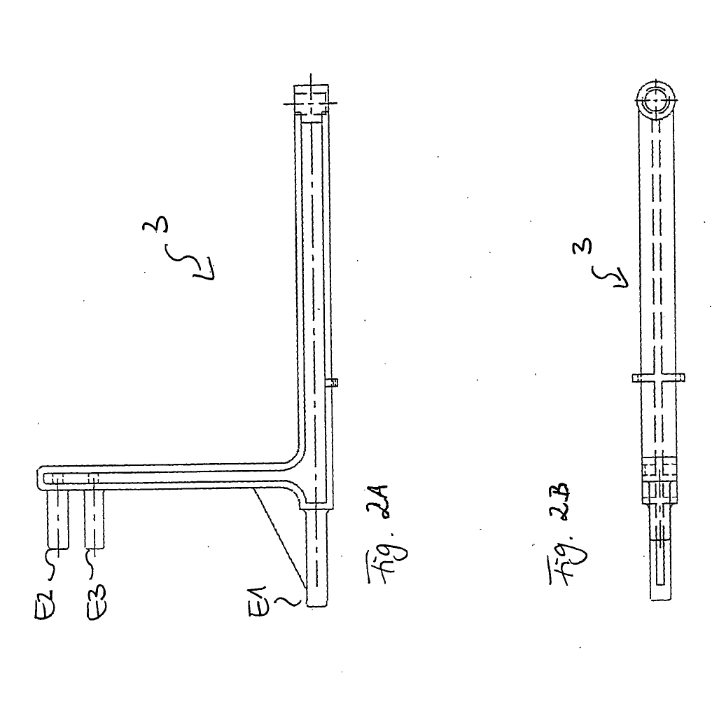

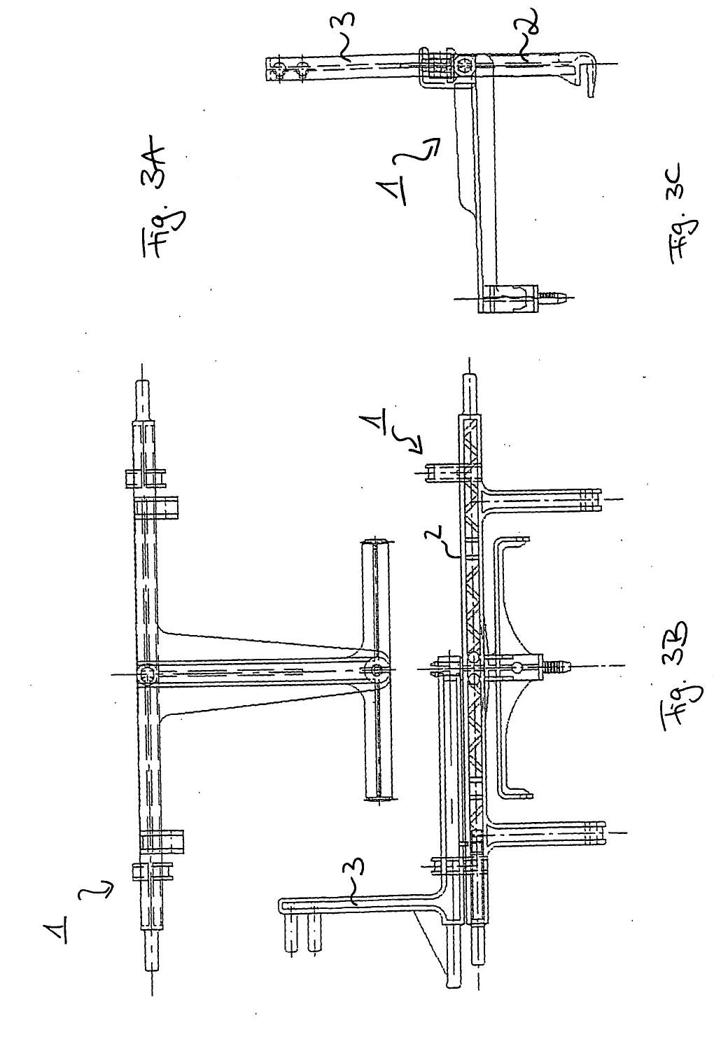

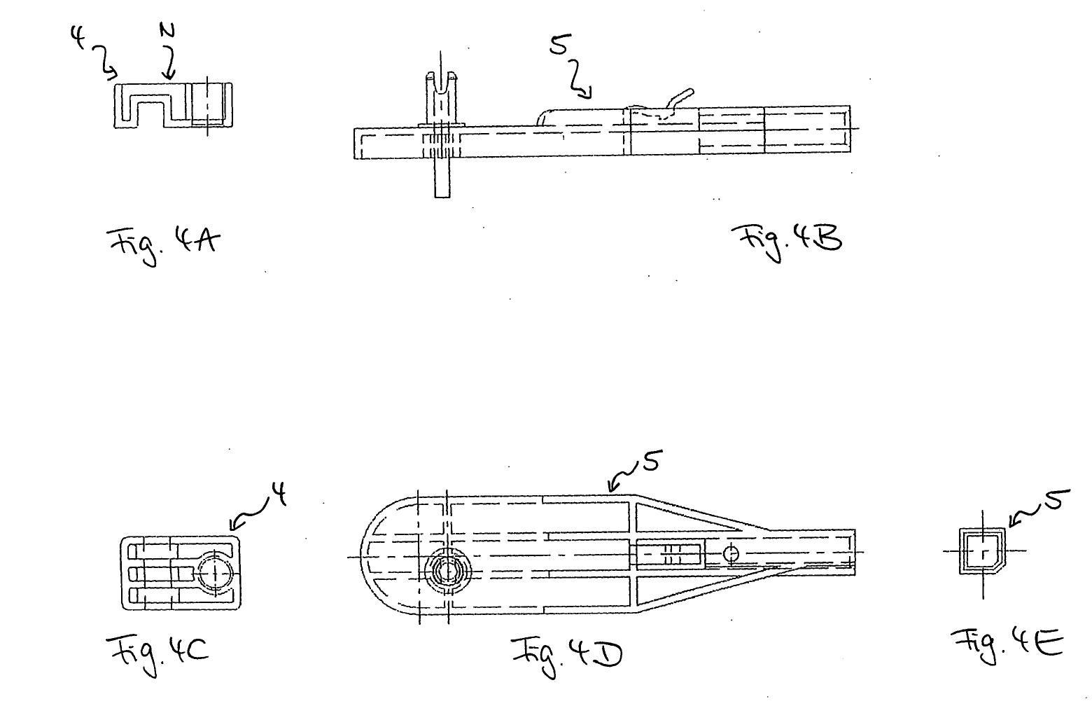

This hook comprises a basic structure 2, visible in FIGS. 1A to 1C, with various engagement sections to be inserted into openings that are present in a vehicle door. Specifically, the hooks H1 and H2 serve to fix the door hook in the window shaft of a door in that they extend behind the window fold; one of the bar ends B1 or B2 (depending on whether it is a left-hand or a right-hand door) catches in openings available in a door so as to prevent the door hook from wobbling; and the peg Z engages an opening in the door in which a door lining is ordinarily fastened. FIGS. 2A and 2B show an L-bar 3 that can be pivotably set onto this basic structure, and in FIGS. 3A to 3C overall views of the door hook 1 are shown. When attached, the pivoted L-bar 3 is moved to various rotational positions in the course of the production sequence, and by means of its engagement sections E1 to E3, which are apposed to or inserted into adjacent parts of the vehicle body, it prevents the door from swinging out of position and, where necessary, ensures that it can be fixed in a more widely open position.

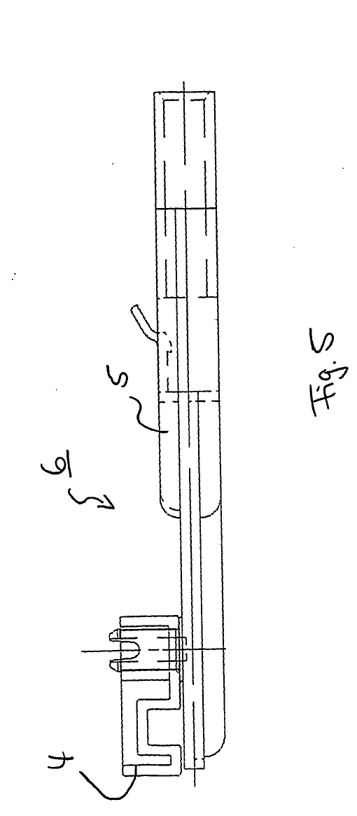

The FIGS. 4A to 4E show in side and plan views and also in a sectional view (FIG. 4E) two individual plastic components 4, 5 of a cover hook 6 for supporting a raised engine-compartment cover, according to another embodiment of the invention; then FIG. 5 shows these plastic parts in the assembled state. When in use this assembly is set onto a metal rod (not shown) and locked into place there, so that together with the rod it forms a processing means of the kind in accordance with the invention. The metal rod has an annular section which, although designed to be engaged by a handling robot, is also useful for manual operations.

The smaller part 4 of the cover hook 6 shown in FIGS. 4A and 4C is set onto the larger part shown in FIGS. 4B, 4D and 4E by rotation, resulting in the configuration shown in FIG. 5. While in use, a receiving hook on the engine-compartment cover is inserted into the groove N of the smaller part, and the cover is pressed upward by means of the rod. With the processing means composed of the plastic part and the metal rod, the cover is held open at the desired angles with no risk of its falling shut, and the plastic part is fixed so that it cannot be lost.

After these processing stages have been completed, the plastic part can be readily “unclipped” from the metal rod, with no need for complicated manipulations such as screwing, traction or the like. Then any impurities are removed with lacquer in the customary manner and the plastic part is sent on for recycling, as described above.

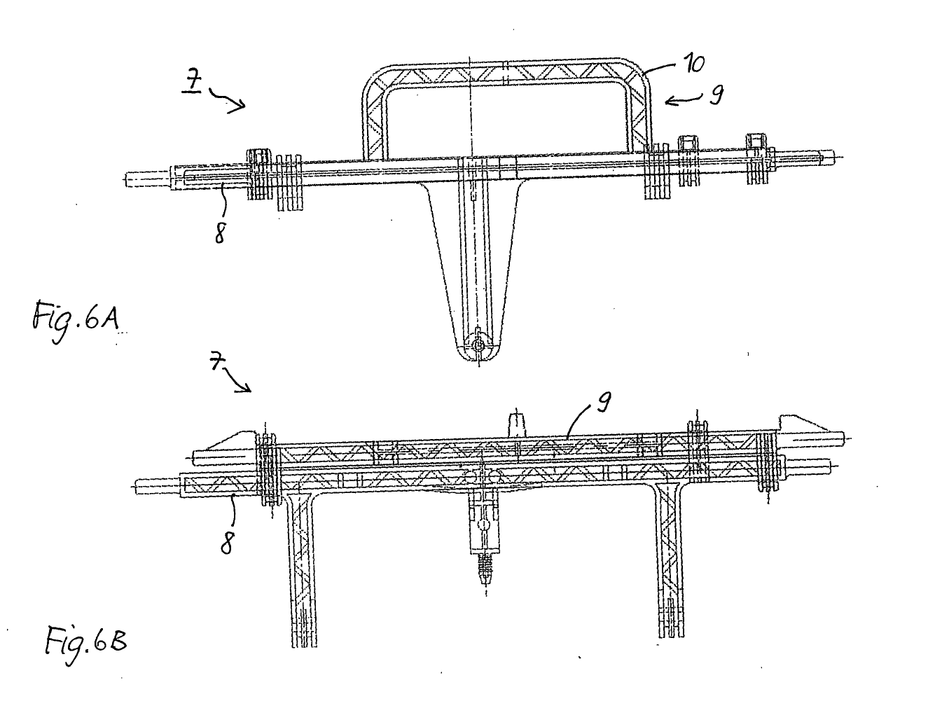

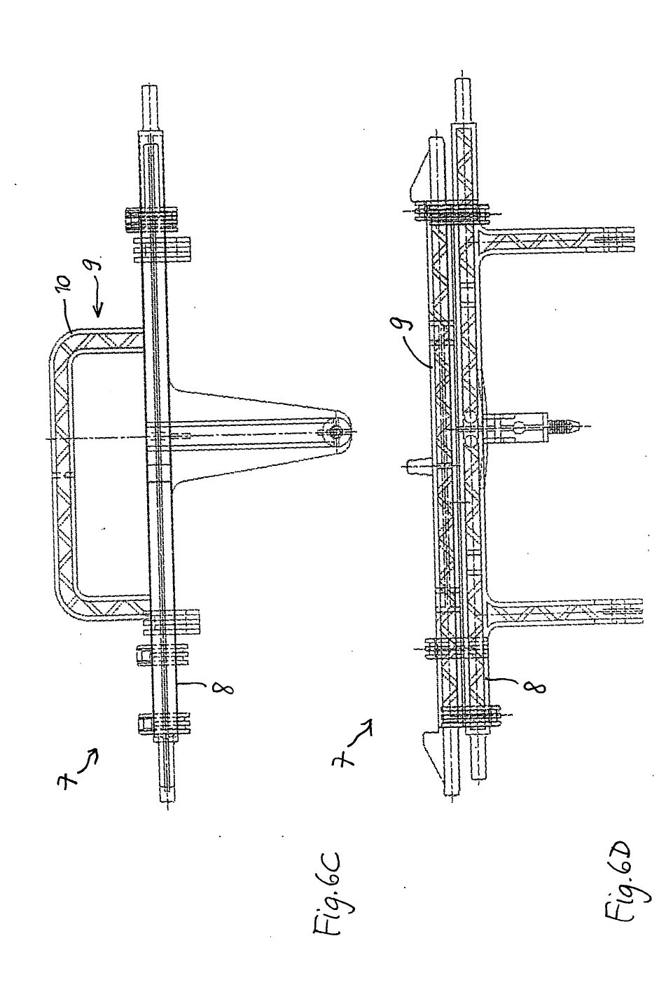

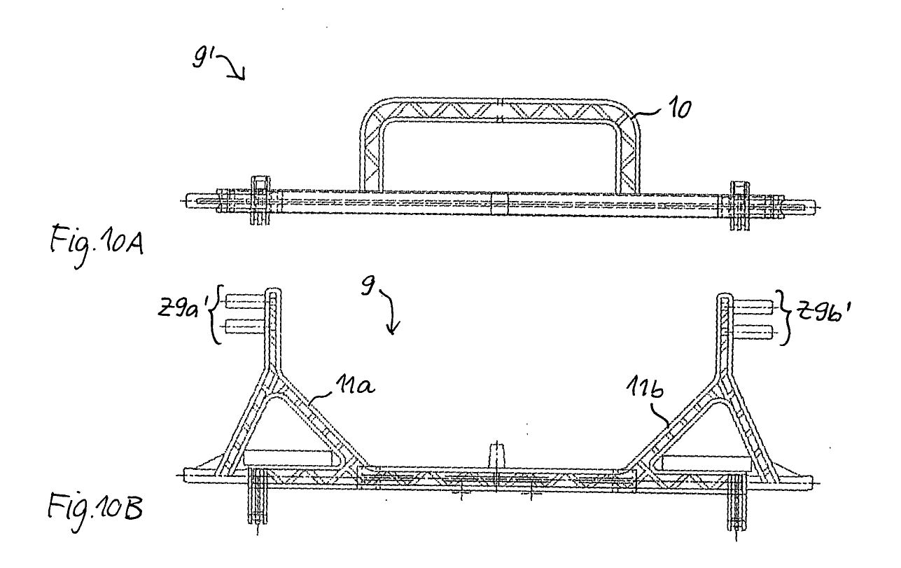

Two modifications of the door hook represented in FIGS. 1A to 3C are shown in FIGS. 6A to 8B and 9A to 10B, respectively. The door hook 7, shown in the assembled state in FIGS. 6A to 6D, is the simpler of these two designs, whereas the door hook 7′, shown assembled in FIGS. 9A to 9D, is a variant with added functions that allow it also to be used during the CDP process.

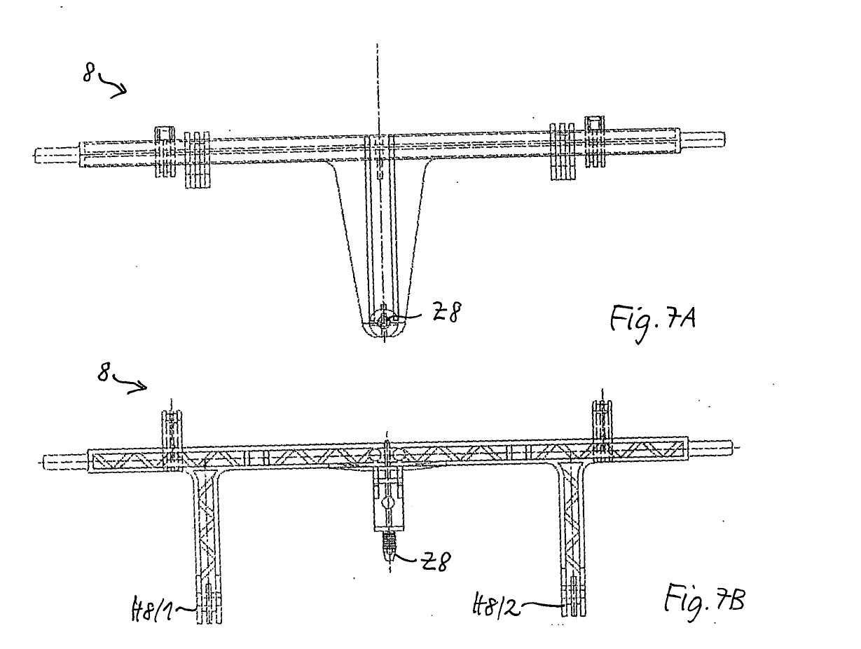

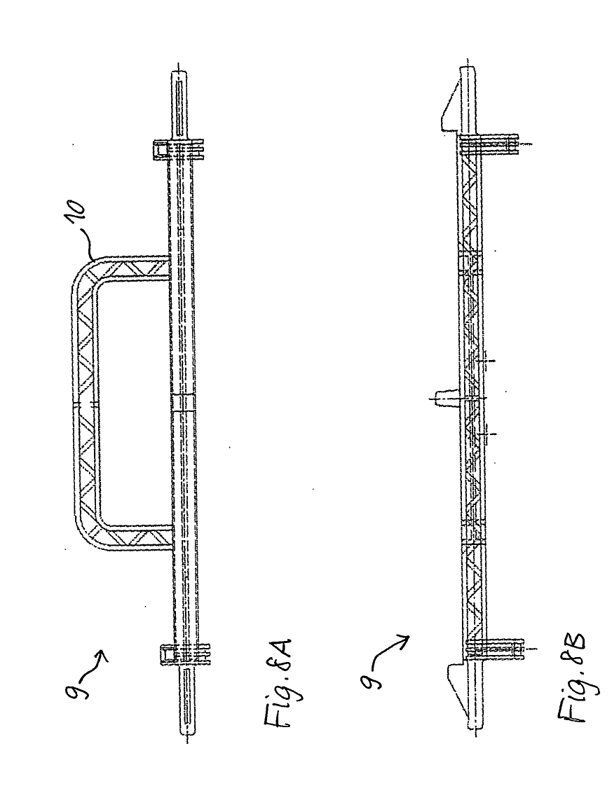

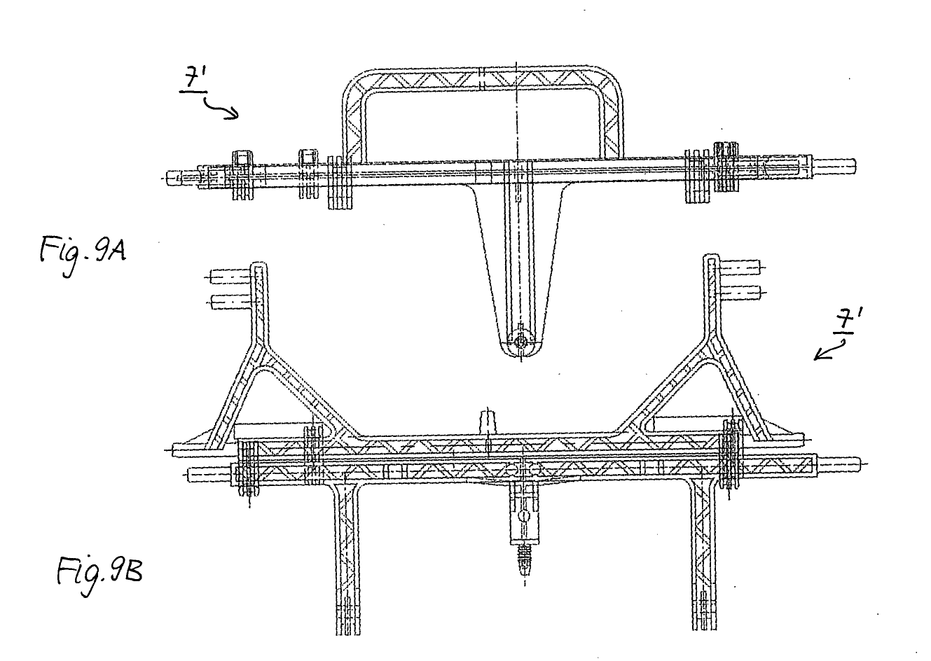

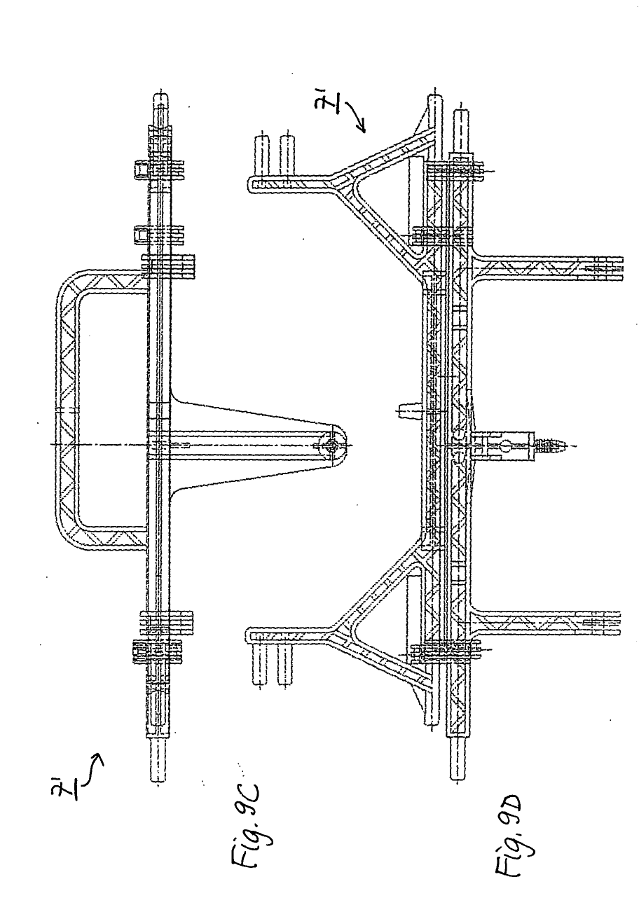

The door hook 7 consists of a basic part 8 (FIG. 7A,B) and a part that can be linearly displaced thereon, the so-called sliding element 9 (FIG. 8A,B). On the sliding element 9 is provided a U-shaped handle 10 with which to move the door hook 7, either manually or by engagement with an appropriately shaped gripping section of a robot, in particular in order to lock the opened door in position or to release the locking by a purely translational movement, namely a linear displacement of the sliding element 9 relative to the basic structure 8.

As in the first embodiment described above, the basic structure 8 here comprises a peg Z8 that projects out of its middle region in order to engage a correspondingly shaped, substantially circular door opening, as well as two hook sections H8/1 and H8/2 to be inserted into a window shaft or behind a window fold of the door. It is evident that these and other pegs (not described in detail here) at the ends of the basic structure 8 or sliding element 7 are in each case connected to one another by way of linearly extending parts of the profile, and in some cases are joined thereto by extension pieces projecting at right angles.

In the case of the door hook 7′ shown in FIGS. 9A to 10B the same basic structure 8 is used as in the design described above, but there is a more elaborately constructed sliding element 9′ with two additional brackets 11A and 11B, at the ends of which are mounted additional pairs of pegs Z9a′ and Z9b′ to provide extra possibilities for fixation in the context of CDP. The mechanism for locking and unlocking is the same as that in the simpler design previously described.

The door hook described above is placed in position during the early stage of assembly and remains in the door until the latter is permanently mounted. Because of the “sliding technique” it makes possible, the following functions are provided for during the relevant processing steps:

a) opening the doors,

b) closing the doors and locking them in position,

c) locking the doors during transport within the factory (to prevent them from swinging open and to avoid damage that would be associated with such an event),

d) painting by robots that possess the appropriate gripping means for opening and closing the doors, or manual painting with manual actuation of the apparatus.

No additional processing means are needed for seating in the B or C column to secure the door during the painting procedure.

In a further modified design (not illustrated by a drawing here) the U-shaped bar of the sliding element is replaced by a plate- or ring-shaped handle, which under certain conditions is still better for handling by a robot, while simultaneously also enabling adequate manual actuation.

The implementation of the invention is not restricted to the examples described above and the highlighted aspects, but is also possible in a large number of further modifications within the competence of one skilled in the art.

While the invention has been described in terms of various specific embodiments, those skilled in the art will recognize that the invention can be practiced with modification within the spirit and scope of the claims.

What is claimed is:

1. Automobile door or compartment-cover holder to fix in position a door or a cover for an engine or luggage compartment of an automobile during a processing event in the manufacturing procedure, in particular the application of a CDP coating and/or paint, constructed as a multi-part plastic holder or combined plastic-metal holder with contact or engagement sections disposed at or near more than one end to cooperate with engagement sections on parts of the vehicle body in order to fix the components at a pre-specified distance from one another, such that the engagement sections have a substantially peg-like structure or are shaped like a flat hook, and each set of two contact or engagement sections is connected together by way of a holder section that extends linearly or is bent at substantially a right angle.

2. Automobile door or compartment-cover holder to fix in position a door or a cover for an engine or luggage compartment of an automobile during a processing event in the manufacturing procedure, in particular the application of a CDP coating and/or paint, constructed as a multi-part plastic holder or combined plastic-metal holder with contact or engagement sections disposed at or near more than one end to cooperate with engagement sections on parts of the vehicle body in order to fix the components at a pre-specified distance from one another, comprising an elongated first plastic part, at the one end of which is provided an engagement section, in particular having a sleeve shape, to engage an elongation rod, and its other end bears a second plastic part, pivotally mounted on a peg that projects perpendicular to the longitudinal extent of the first plastic part, for the purpose of engaging an engagement section of an engine-compartment cover or a luggage-compartment cover.

3. Automobile door or compartment-cover holder according to claim 1, comprising a U-shaped or substantially plate-shaped handling section, so constructed as to be grasped manually or gripped by a gripping tool of a handling robot.

4. Automobile door or compartment-cover holder according to claim 2, such that the second plastic part has a substantially cuboid external shape, with a cylindrical first aperture to be engaged by the peg of the first plastic part and with at least one elongated second aperture to be engaged by a section of a vehicle body part, in particular a bent metal bar.

5. Automobile door or compartment-cover holder according to claim 1, such that the plastic holder or a plastic part of the plastic-metal holder consists to a substantial extent of a plastic resistant to high temperatures, which can be used in the long term at a temperature of at least 170° C.

6. Automobile door or compartment-cover holder according to claim 1, such that the plastic holder or a plastic part of the plastic-metal holder consists of glass-fiber-reinforced polyamide containing a proportion of reinforcing filler between 0.1% and 40%, in particular between 5% and 20%.

7. Automobile door or compartment-cover holder according to claim 1, such that the plastic holder or a plastic part of the plastic-metal holder consists to a substantial extent, in particular 50% or more and preferably 70% or more, of recycled material.

8. Automobile door or compartment-cover holder according to claim 1, such that the peg or hook sections have a pre-specified degree of elasticity in both material and shape, so that they can be inserted into apertures provided for them in the body parts without damaging the surface, and are connected to one another by slightly flexible profile parts of the basic structure of a plastic holder, in particular having the basic shape of a U or double-T profile.

9. Automobile door or compartment-cover holder according to claim 1, comprising being constructed as a door hook, having two hooks to engage the window shaft of a door and at least one peg to engage an opening in the door that serves for fixation of a door lining.

10. Automobile door or compartment-cover holder according to claim 1, comprising being constructed as a door hook extending within a plane defined by connecting sections between the engagement sections, wherein the substantially plate-shaped handling section has the shape of a circular ring in plan view and lies within a plane parallel to the plane in which the holder extends.

11. Automobile door or compartment-cover holder according to claim 1, comprising being constructed as a door hook composed of two parts, firstly a basic structure with several engagement sections to engage apertures in a vehicle door as well as, if desired, apertures or bearing surfaces in an adjacent part of the vehicle body, and secondly a substantially L-shaped pivot bar that can be pivotally set onto the basic structure and comprises engagement sections to engage apertures or to abut against sections of the vehicle body in the vicinity of the door.

12. Automobile door or compartment-cover holder according to claim 1, comprising a locking device that can be locked or released by linearly shifting two plastic parts with respect to one another, in order to fix the door or compartment cover of the automobile at a predetermined distance from the basic vehicle body or to release this fixation.

13. Automobile door or compartment-cover holder according to claim 12, such that the U-shaped or substantially plate-shaped handling section is attached to the locking device and is used to lock or release that device.

14. Automobile door or compartment-cover holder according to claim 2, such that the plastic holder or a plastic part of the plastic-metal holder consists to a substantial extent of a plastic resistant to high temperatures, which can be used in the long term at a temperature of at least 170° C.

15. Automobile door or compartment-cover holder according to claim 2, such that the plastic holder or a plastic part of the plastic-metal holder consists of glass-fiber-reinforced polyamide containing a proportion of reinforcing filler between 0.1% and 40%, in particular between 5% and 20%.

16. Automobile door or compartment-cover holder according to claim 2, such that the plastic holder or a plastic part of the plastic-metal holder consists to a substantial extent, in particular 50% or more and preferably 70% or more, of recycled material.

17. Automobile door or compartment-cover holder according to claim 2, such that the peg or hook sections have a pre-specified degree of elasticity in both material and shape, so that they can be inserted into apertures provided for them in the body parts without damaging the surface, and are connected to one another by slightly flexible profile parts of the basic structure of a plastic holder, in particular having the basic shape of a U or double-T profile.
